(19) United States
(12) Patent Application Publication
(10) Pub. No.: US 2011/0062394 A1
(43) Pub. Date: Mar. 17, 2011

(54) RARE EARTH-DOPED SAPPHIRE FILMS AND RELATED METHODS

(75) Inventors: Raveen Kumaran, Burnaby (CA); Thomas Tiedje, Victoria (CA); Scott Webster, Vancouver (CA); Shawn Penson, Vancouver (CA)

(73) Assignee: UNIVERSITY OF BRITISH COLUMBIA, Vancouver (CA)

(21) Appl. No.: 12/851,427

(22) Filed: Aug. 5, 2010

Related U.S. Application Data
(60) Provisional application No. 61/213,985, filed on Aug. 5, 2009.

(51) Int. Cl. G02B 5/20; C30B 23/08

(52) U.S. Cl. 252/584; 117/108

(57) ABSTRACT

The present invention relates to the growth of single phase rare earth-doped sapphire (α-Al₂O₃) films on substrates by molecular beam epitaxy. The invention provides for composition of matters, neodymium-doped sapphire films, and methods for making and using thin films of this material. The rare earth-doped films of the present invention are especially useful in solid state lasers.

### CROSS-REFERENCE TO RELATED APPLICATIONS

This application claims the benefit of priority to U.S. Provisional Application No. 61/213,985 filed on Aug. 5, 2009, which application is incorporated herein by reference in its entirety for all purposes.

### TECHNICAL FIELD

The present invention relates generally to rare-earth doped materials and, more specifically, to epitaxial neodymium-doped sapphire materials useful as active mediums for waveguide lasers and to related methods.

### BACKGROUND OF THE INVENTION

Sapphire (α-Al₂O₃) is an attractive laser host crystal because of its excellent thermomechanical properties and wide optical transparency. Solid state lasers using sapphire crystals typically involve transition metal dopants such as Ti or Cr due to the size compatibility with the replaced Al ion. There are no known reports of rare-earth doped bulk sapphire crystals suitable for making lasers. It is likely that the equilibrium solubility of rare-earth ions in sapphire is very low at the melting point due to the disparity in size between the small Al ions and large rare-earth ions.

Rare-earth-doped sapphire lasers may be better suited for power scaling since the thermal conductivity of sapphire (33 W/m·K) is large compared to other popular hosts such as YAG (11 W/m·K) or YVO₄ (7 W/m·K) (E. R. Dobrovinskaya, L. A. Lytvynov, and V. Pishchik, in Sapphire: Materials, Manufacturing, Applications (Springer, 2009), pp. 55-176; J. Didierjean, E. Herault, F. Balembois, and P. Georges, Opt. Express 16, 8995 (2008)). While rare-earth-doped sapphire grown by bulk methods is unavailable, some progress has been made by using thin film techniques. Eu-doped sapphire grown by pulsed laser deposition produced distinct emission lines, but extraneous lines from other phases of Al₂O₃ were found to be present as well (G. Wang, O. Marty, C. Garapon, A. Pillonnet, and W. Zhang, Appl. Phys. A 79, 1599 (2004)). The requirement that the dopant ions be placed in identical crystal field sites may be complicated by the much larger size of the rare-earth ions. Examples of rare earth-doped sapphire are thus exceedingly rare.

An optical waveguide is a physical structure that guides electromagnetic waves in the optical spectrum. Common types of optical waveguides include optical fiber and rectangular waveguides. Optical waveguides can be classified according to their geometry (planar, strip, or fiber waveguides), mode structure (single-mode, multi-mode), refractive index distribution (step or gradient index) and material (glass, polymer, semiconductor). Optical waveguides have been used in association with diode-pumped solid-state (DPSS) lasers.

Accordingly, there is a need in the art for new and improved rare-earth doped materials useful as, for example, active mediums for optical waveguide lasers, as well as to related methods. The present invention fulfills these needs and provides for further related advantages.

### SUMMARY OF THE INVENTION

In brief, the present invention relates to the growth of single phase Nd-doped sapphire (α-Al₂O₃) films on substrates by molecular beam epitaxy. Thus, and in an embodiment, the invention provides a method for making rare earth doped sapphire thin films by molecular beam epitaxy. In other embodiments the invention provides for composition of matters, neodymium-doped sapphire films, and methods for making and using thin films of this material. The invention also provides for rare earth doped sapphire films, including Nd:sapphire, for use in solid state lasers.

Thus, and in an embodiment, the present invention is directed to a method of making a rare earth-doped sapphire crystal, comprising: providing a sapphire substrate; providing a source of aluminum; providing a source of a rare earth element; providing a source of oxygen; and, introducing a flux of the aluminum, oxygen and rare earth element onto the substrate under MBE conditions to thereby yield the rare earth-doped sapphire, wherein the rare earth-doped sapphire crystal is in the form of a deposited film on the sapphire substrate. The rare earth element may neodymium (Nd), erbium (Er), or ytterbium (Yb). In addition, the flux of neodymium (Nd) may be adjusted relative to the flux of aluminum (Al) to yield a desired dopant concentration.

In another embodiment, the present invention is directed to single phase rare earth doped sapphire crystal in which the rare earth ions are on the aluminum sites and the concentration of rare earth ions exceeds 0.1 or 0.5 atomic percent. The rare earth element may be neodymium (Nd), erbium (Er), or ytterbium (Yb). When the dopant is neodymium (Nd), the single phase rare earth doped sapphire crystal is capable of producing sharp optical emission lines at wavelengths of between 880-950 nm, or between 1070-1140 nm, or between 1380-1450 nm; the crystal is also capable of producing dominant optical emission lines at wavelengths of about 1096 nm, or about 910 nm, or about 1389 nm; and the crystal has an absorption peak at about 825 nm, or about 833 nm when excited using excitation spectroscopy.

These and other aspects of the present invention will be more evident upon reference to the following detailed description and accompanying drawings.

### BRIEF DESCRIPTION OF THE DRAWINGS

FIG. 1 is an X-ray diffraction plot from a 55 nm Nd:Sapphire film grown on R-plane sapphire showing (a) reciprocal space map of θ/2θ scans for varying sample tilt ω and (b) single θ/2θ scan. The film peak is shifted to lower angle from the substrate peak as a result of neodymium doping. This shift increases with Nd concentration. Pendellösung fringes reflect the good overall structural quality of the film.

FIG. 2 is an X-ray diffraction plot from a 107-nm-thick 0.5 at. % Nd:sapphire film grown on A-plane sapphire, showing (a) a reciprocal space map consisting of θ/2θ scans for varying sample tilt ω and (b) a single θ/2θ scan. The film peak is shifted to a lower angle from the substrate peak as a result of Nd doping. This shift increases with Nd concentration. Pendellösung fringes reflect the good overall structural quality of the film. The film thickness and Nd composition were measured by RBS.

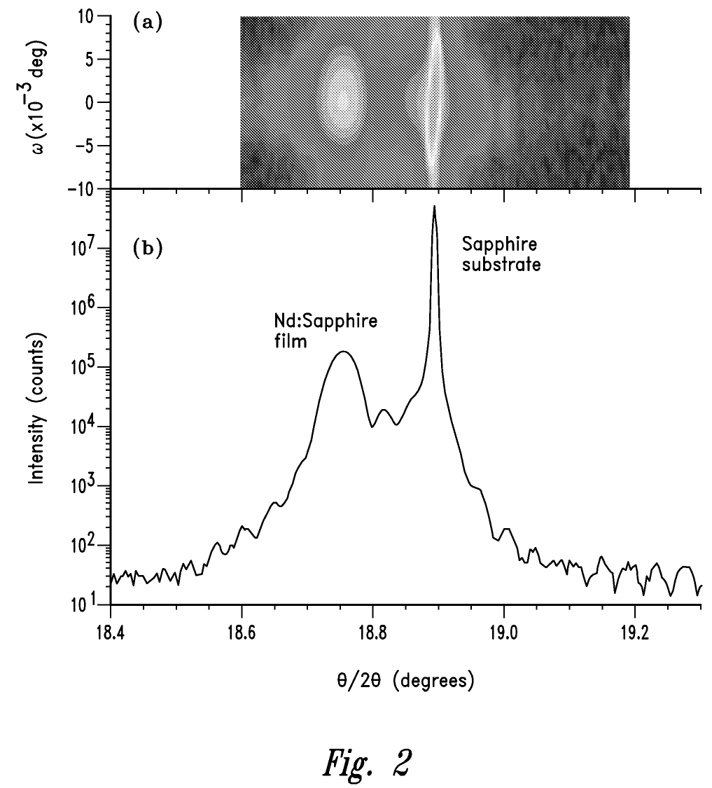

FIG. 3 shows room temperature polarized emission cross sections of Nd:Sapphire showing transitions from the ⁴F_{3/2} manifold to the ⁴I_{9/2}, ⁴I_{11/2} and ⁴I_{13/2} manifolds. π and σ polarizations occur when the E field is parallel and perpendicular to the optic axis respectively. σ-τ, the product of emission cross section σ (not to be confused with polarization) and upper state lifetime τ are listed for the strongest emission lines involving the ⁴I_{9/2} and ⁴I_{11/2} manifolds. The inset shows the room temperature energy levels for the metastable, as well as two lowest energy manifolds.

FIG. 4 shows room temperature π-polarized absorption cross sections of Nd:Sapphire measured using excitation spectroscopy. Measurements were taken at one nanometer intervals. Peak wavelengths (in nm) are labeled.

### DETAILED DESCRIPTION OF THE INVENTION

The present invention in an embodiment relates to the growth of single phase Nd-doped sapphire (α-Al₂O₃) films on substrates by molecular beam epitaxy (MBE). The emission spectra of such films feature sharp lines characteristic of Nd-doped crystalline hosts, implying a uniform crystal field effect on the Nd³⁺ dopants. The collection of sharp lines constitute an emission spectrum unique to Nd-doped sapphire. Among the emission lines, the 1096 nm line in the ⁴F_{3/2}→⁴I_{11/2} manifold is dominant and thus a candidate for lasing action. This emission line is further in the infrared compared to the dominant lines of other Nd-doped crystals such as Nd:YAG (1064 nm), Nd:YVO₄ (1064 nm) and Nd:YLF (1047 nm). In the context of the present invention, single phase means only corundum phase x-ray diffraction lines in a theta-2theta scan.

Solid state laser materials deposited in the form of thin films in accordance with the present invention may be fabricated into planar waveguide lasers following techniques used in the semiconductor industry. These lasers have promising applications such as, for example, high power sources in laser televisions.

The 1096 nm line of Nd:Sapphire has a large sigma-tau product (114×10⁻²⁴ cm²), comparable to the 1064 nm line of Nd:YVO⁴ (100×10⁻²⁴ cm²s⁻¹) and almost double the 1064 line of Nd:YAG (60×10⁻²⁴ cm²s⁻¹). The sigma-tau product is a measure of gain efficiency and is inversely related to the threshold power required for lasing. While Nd:YVO₄ has a high gain efficiency, it is typically only used for low power applications due to its low thermal conductivity Nd:YAG is preferred for high power applications due to its higher thermal conductivity even though the gain efficiency is lower.

From the unique emission spectrum of Nd:Sapphire, other possible lasing lines include 910 nm and 1389 nm, which are the strongest transitions between the upper ⁴F_{3/2} manifold and the lower ⁴I_{9/2} and ⁴I_{13/2} manifolds, respectively. The absorption spectrum of Nd:Sapphire is also unique, where the main absorption peaks of 825 nm and 833 nm are shifted further into the infrared compared to other Nd-doped crystals (e.g., YAG and YVO₄). The upper state lifetime was measured to be about 96 microseconds.

Thus, and in one example of the invention, a method for the preparation of rare-earth doped sapphire films (useful for lasing action) by molecular beam epitaxy is provided, the method comprising at least the following steps:
providing a sapphire substrate;
providing a source of aluminum;
providing a source of a rare earth element;
providing a source of active oxygen;
introducing a flux of the aluminum, oxygen and rare earth element onto the substrate under MBE conditions.

Molecular Beam Epitaxy (MBE) may be used to grow high-quality single crystal oxide films. In the MBE process, directed thermal beams of atoms or molecules from heated effusion cells react on the clean surface of a substrate held at high temperature under vacuum conditions to form an epitaxial film. The effusion cell temperatures control the beam fluxes, and mechanical cell shutters permit rapid switching of beam species and thus abrupt changes in layer composition and doping. A stainless-steel growth chamber is equipped with an ion pump, turbomolecular pump, cryo-pump and sublimation pump yielding base pressures below 10^{̂-5} mBar. In addition, circulating cold water-filled cryo-shrouds surround the effusion cells and the substrate. Thus, the substrate sees only cold walls onto which most impurities and re-evaporated layer constituents condense.

The stoichiometry of the deposited material is controlled by independent regulation of the intensity of the molecular beams. Growth rates are typically about 1 mono-layer per second. As a result, the thickness of the grown layer can be controlled with high precision. Moreover, it is possible to profile the dopant concentration in the growth direction. MBE growth is typically carried out at about half the melting temperature, whereas bulk crystal growth from a melt is necessarily carried out at the melting point. The low growth temperature of MBE makes it possible to grow crystals with lower equilibrium defect densities such as anti-sites and vacancies and freeze in metastable phases or phases that are unstable at high temperature.

In another example of the invention rare earth-doped sapphire may be fabricated by thin film deposition on a substrate by a method comprising the following characteristics:

a. The substrate may be sapphire with an orientation of A, M, R or C-plane.
i. The substrate may be annealed in a furnace in air to improve the surface morphology by creating atomic terraces.

b. The deposition technique is molecular beam epitaxy where
i. The rare earth and Al are evaporated onto a heated substrate under an overpressure of oxygen.
   1. The source materials may be either elemental rare earth or Al, compounds of Al₂O₃ or rare earth oxides, or a combination of elemental and compound sources.
   2. A flux of the source materials may be produced by radiative heating from a filament, or bombardment with an electron beam.
ii. The Al flux determines the growth rate.
iii. The rare earth flux is adjusted relative to the Al flux to yield the desired dopant concentration.
iv. The substrate temperature may be in the range between 300° C. and 1100° C., or in the range between 300° C. and 2000° C.
v. Oxygen is supplied in the form of either molecular O₂ gas or active oxygen plasma. The growth chamber overpressure may range from 1×10⁻⁷ torr to 1×10⁻³ torr. The active oxygen plasma may be generated using an RF source with an input power as low as 10 W. Typical values range between 100 W and 500 W.

The rare earth elements that can be used include neodymium (Nd), erbium (Er), ytterbium (Yb) thulium (Tm), and holmium (Ho).

In another example of the invention Nd-doped sapphire may be fabricated by thin film deposition on a substrate by a method comprising the following characteristics:

1) Nd-doped sapphire may be fabricated by thin film deposition on a substrate where
a. The substrate may be sapphire with an orientation of A, M, R or C-plane.
   i. The substrate may be annealed in a furnace in air to improve the surface morphology by creating atomic terraces.
b. The deposition technique is molecular beam epitaxy where
   i. Nd and Al are evaporated onto a heated substrate under an overpressure of oxygen.
      1. The source materials may be either elemental Nd or Al, compounds of Al₂O₃ or Nd₂O₃, or a combination of elemental and compound sources.
      2. A flux of the source materials may be produced by radiative heating from a filament, or bombardment with an electron beam.
   ii. The Al flux determines the growth rate.
   iii. The Nd flux is adjusted relative to the Al flux to yield the desired dopant concentration.
   iv. The substrate temperature may be in the range between 300° C. and 1100° C., or in the range between 300° C. and 2000° C.
   v. Oxygen is supplied in the form of either molecular O₂ gas or active oxygen plasma. The growth chamber overpressure may range from 1×10⁻⁷ torr to 1×10⁻³ ton. The active oxygen plasma may be generated using an RF source with an input power as low as 10 W. Typical values range between 100 W and 500 W.

In another example of the invention a composition of matter of neodymium-doped sapphire is provided. Thus, a composition of matter of neodymium-doped sapphire, in which the Nd dopant is in the range 0.01% to 10% referenced to the atomic concentration of Al in sapphire, is disclosed herein.

Other examples of the invention include a composition of matter comprising Neodymium-doped sapphire where:
c. The atomic concentration of Nd is between 0.01% and 10% referenced to the concentration of Al in sapphire.
d. The Nd dopant ions are located on identical local atomic bonding sites in the sapphire host crystal with equivalent crystal field.
   i. Possibilities for the dopant site may include either the aluminum ion site or an interstitial site.
e. The host crystal, sapphire (α-Al₂O₃), may be in the form of single crystal, polycrystalline or nanocrystalline as long as the local atomic bonding sites are substantially identical.

Other examples of the invention also provide a composition of matter, and a method of preparing that composition of matter, such that the Nd-doped sapphire may be excited to produce an optical emission spectrum featuring sharp emission lines. In some embodiments, the primary emission line for Nd-doped sapphire in the infrared is at 1096 nm and is suitable as a lasing line.

Further examples of the invention include a composition of matter comprising rare earth-doped sapphire where:
a. The atomic concentration of the rare earth is between 0.01% and 10% referenced to the atomic concentration of Al in sapphire.
b. The rare earth dopant ions are located on identical local atomic bonding sites in the sapphire host crystal with equivalent crystal field.
   i. Possibilities for the dopant site may include either the aluminum ion site or an interstitial site
c. The host crystal, sapphire (α-Al₂O₃) may be in the form of single crystal, polycrystalline or nanocrystalline as long as the local atomic bonding sites for the rare earth elements are substantially identical.

Other examples of the invention also provide a composition of matter, and a method of preparing that composition of matter, such that the rare earth-doped sapphire can be excited to produce an optical emission spectrum featuring sharp emission lines. The rare earth elements that may be used include neodymium (Nd), erbium (Er) and ytterbium (Yb). Due to the chemical similarity among the various rare earth elements other rare earth elements which are known in the art to be useful in solid state lasers may also be incorporated into sapphire under similar growth conditions and show sharp emission spectra analogous to Nd.

### EXAMPLES

The examples provided herein are to aid in the illustration and description of the invention, without meaning to limit the invention to the materials or methods described in these examples. It should be understood that these examples are illustrative and should not be considered limiting with respect to the spirit or scope of the invention. Furthermore, alternative embodiments and means of practicing the invention will become clear to one skilled in the art by these representative examples.

In the example below, Nd-doped sapphire is described, however the invention is generally applicable to other rare earth elements. The rare earth elements that may be used include neodymium (Nd), erbium (Er) and ytterbium (Yb). Due to the chemical similarity among the various rare earth elements other rare earth elements which are known in the art to be useful in solid state lasers may also be incorporate into sapphire under similar growth conditions and show sharp emission spectra analogous to Nd.

Films were grown using plasma assisted MBE with effusion cell sources for aluminum and neodymium metal and a 300 W plasma source for generating active oxygen. The background oxygen pressure during growth was 6×10⁻⁶ torr. The sapphire substrates were furnace annealed in air at 1150° C. for 8 hours to generate atomic terraces on the surface.

Nd:Sapphire films up to 1 μm thick were grown between 400-800° C. at growth rates of 0.5-1 nm/min. The Nd doping level was up to 2 atomic percent relative to the Al concentration. The growth temperature is more than a factor of two below the melting temperature, thereby making it possible to fabricate non-equilibrium phases not accessible in growth from a melt. Films grown on R, A and M-plane sapphire substrates were single crystal and followed the substrate orientation. Films grown on C— plane sapphire under similar growth conditions were not sapphire but instead (111) γ-Al₂O₃. Emission from the non-sapphire films was broad and resembled that from Nd:Glass.

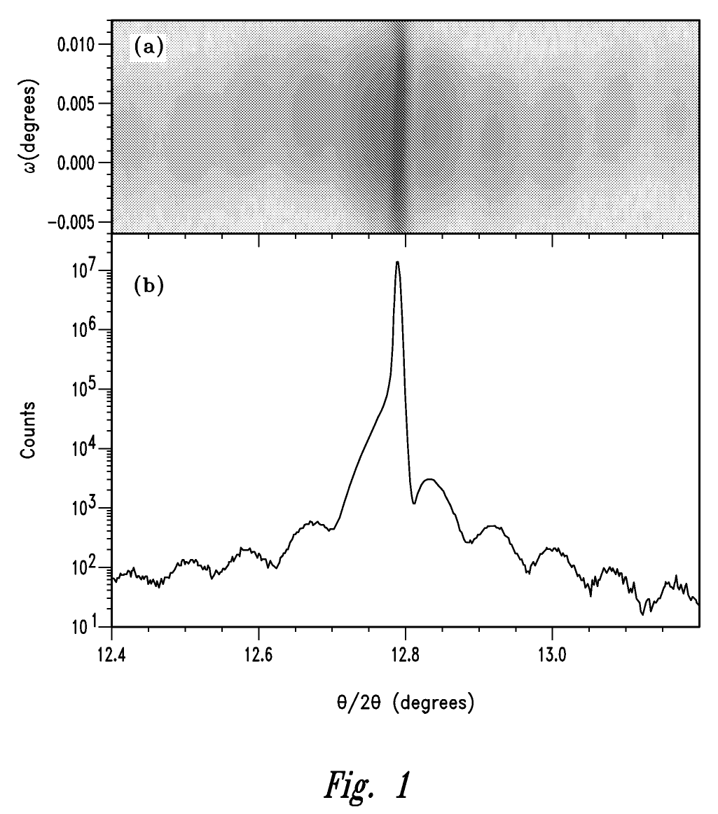

Thin (˜100 nm) Nd:Sapphire films with less than 1 nm rms surface roughness were grown at 400-500° C. FIG. 1 shows an x-ray diffraction spacemap of bragg angle θ/2θ scans with varying sample tilt ω for a 55 nm Nd:Sapphire film grown on R-plane sapphire. The film and substrate peaks coincide in ω indicating that the film is oriented with the substrate and not tilted. The small shift in film peak in the 0 direction corresponds to a 0.3% increase in vertical interplanar spacing and is due to the small Nd dopant concentration (<1 at %, referenced to Al) in this example. We observed larger shifts in films with higher Nd concentration, confirming that Nd ions are incorporated into the film. The film surface maintained the atomic terrace profile and in this case had an rms roughness of 0.3 nm as measured by atomic force microscopy. Due to the high crystalline quality and smooth surface of the film, pendellösung fringes arising from the interference of the incident and diffracted x-ray beam are observed.

Since sapphire is uniaxial, the emission spectrum is polarization dependent. In the case of the films deposited on M or A-plane sapphire the optic axis is in the plane of the surface. The polarized emission from a 1 μm M-plane Nd:Sapphire film pumped with a 200 mW 798 nm diode laser was passed through a calcite polarizer and measured by an InGaAs detector. The resolution of the measurement was 0.2 nm, the throughput of the optical system was calibrated using a tungsten lamp. The emission spectrum features a unique set of sharp

The emission spectrum was used to calculate σ-τ, the product of emission cross section σ (not to be confused with the polarization) and lifetime τ, from the equation:

$${σ}^{pol} ( λ ) \cdot τ = {\frac{3 {λ}^{5} {I}^{pol} ( λ )}{8 π {cn}^{2}} [ \int ( {I}^{π} ( λ ) + 2 {I}^{σ} ( λ ) ) λ d λ ]}^{- 1}$$

where n is the refractive index, I^{pol} is the polarized emission intensity and pol is the polarization π or σ which is parallel or perpendicular to the optic axis respectively. The σ-τ product is proportional to the gain efficiency and inversely proportional to the lasing threshold power. Among the emission lines, the 1096 nm line in the ⁴F_{3/2}→⁴I_{11/2} manifold is dominant. The dominant π polarized line at 1096 nm has a σ-τ product of 114×10⁻²⁴ cm²s, comparable to Nd:YVO₄ (100×10⁻²⁴ cm²s).

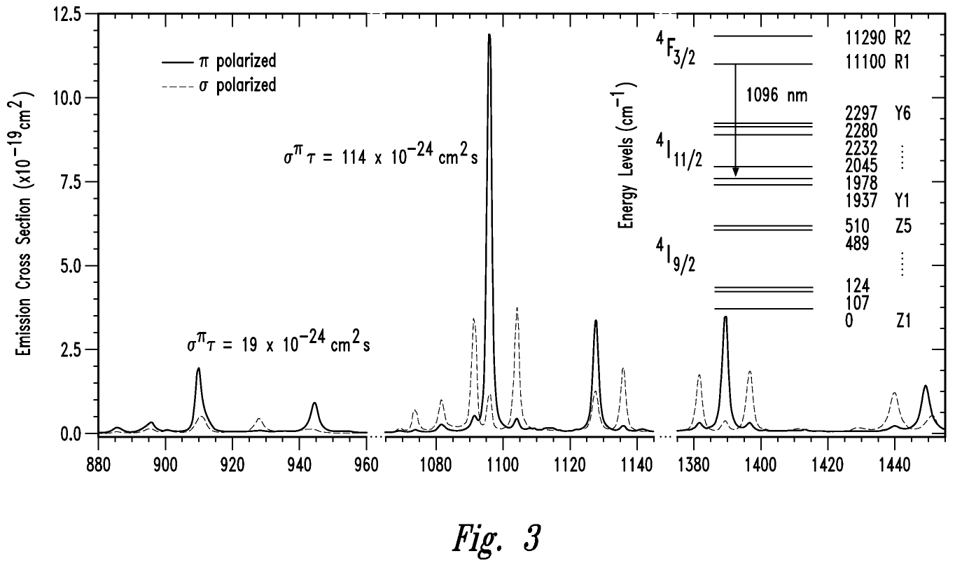

The lifetime was measured using mechanically chopped pulses from a 1 W 514 nm Ar⁺ laser with emission collected by a photomultiplier tube. The time resolved signal was current-amplified and monitored on an oscilloscope. A lifetime of 96 μs was measured for Nd:Sapphire. Using this lifetime and the σ-τ product, the emission cross section of 11.9×10⁻¹⁹ cm² was obtained for the 1096 nm line. For comparison, the emission cross sections of the 1064 nm line of Nd:YAG and Nd:YVO₄ are 2.6×10⁻¹⁹ cm² and 13.5×10⁻¹⁹ cm² respectively. FIG. 3 shows the polarized emission for transitions from the ⁴F_{3/2} manifold to the ⁴I_{9/2}, ⁴I_{11/2} and ⁴I_{13/2} manifolds.

The inset of FIG. 3 shows the energy levels of the metastable as well as two lowest energy manifolds. These levels were identified using low temperature (8 K) emission measurements to suppress transitions from the upper Stark energy level in the ⁴F_{3/2} metastable manifold. The remaining transitions corresponded to the expected number of levels produced by the crystal field splitting of each Nd³⁺ multiplet.

Since the Nd:Sapphire films are thin, direct transmission-based absorption measurements were unsuccessful. Excitation spectroscopy was used instead, whereby a

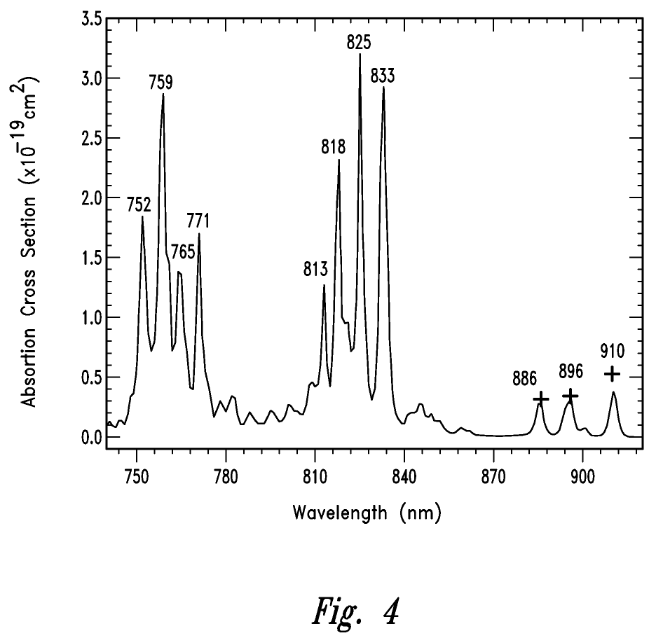

From the absorption data in FIG. 4, suitable laser pump wavelengths would be 825 or 833 nm with absorption cross sections of ˜3×10⁻¹⁹ cm². This compares to 0.6×10⁻¹⁹ cm² and 2.5×10⁻¹⁹ cm² for Nd:YAG and Nd:YVO₄ respectively.

RHEED is an electron diffraction technique we used to monitor the film quality while it was being grown. It did not influence the creation of the material, but rather indicated to us if our film was crystalline, polycrystalline or amorphous. RHEED involves focusing an electron beam at the sample at grazing incidence and monitoring the subsequent diffraction pattern on a fluorescent screen. That pattern describes the crystal structure of the topmost monolayers of the sample, be it substrate prior to growth or the film once the growth has started. The growth was started by first heating up the substrate, making sure the RHEED pattern shows that the surface was crystalline and smooth. The substrate may be any orientation of sapphire, but for making a useful waveguide laser the preferred orientation would be A or M-plane. Oxygen gas is introduced into the chamber in the 10̂-6-10̂-5 torr range, then the plasma was ignited using the RF power amplifier. The power range may be anywhere from tens of watts to hundreds of watts. The oxidizing species used in the plasma source does not necessarily have to be oxygen gas. Other candidates include a mixture of H₂ and O₂ gas (to make water plasma), N₂O, etc. We checked that the RHEED pattern was still good, then opened the Al shutter to start the growth.

These examples demonstrate the use of the invention to prepare single crystal neodymium-doped sapphire (α-Al₂O₃) thin films by molecular beam epitaxy on sapphire substrates. The narrow Nd emission lines indicate that the Nd ions are all located on sites with the same crystallographic symmetry. The same growth method is also applicable to sapphire doped with other rare-earth ions. The absence of reports in the literature of rare-earth-doped bulk sapphire suggests that the molecular beam epitaxy material is a non-equilibrium phase, inaccessible in growth from a melt. The strongest emission line in the Nd-doped material is at 1096 nm with a large emission cross section comparable to the 1064 nm line of Nd:YVO₄. This property, combined with the high thermal conductivity of sapphire, means that Nd:Sapphire is attractive for the active medium in diode pumped waveguide lasers.

While the present invention has been described in the context of the embodiments illustrated and described herein, the invention may be embodied in other specific ways or in other specific forms without departing from its spirit or essential characteristics. Therefore, the described embodiments are to be considered in all respects as illustrative and not restrictive. The scope of the invention is, therefore, indicated by the appended claims rather than by the foregoing description, and all changes that come within the meaning and range of equivalency of the claims are to be embraced within their scope.

What is claimed is:

1. A method for making a rare earth-doped sapphire crystal, comprising:
providing a sapphire substrate;
providing a source of aluminum;
providing a source of a rare earth element;
providing a source of oxygen; and
introducing a flux of the aluminum, oxygen and rare earth element onto the substrate under MBE conditions to thereby yield the rare earth-doped sapphire, wherein the rare earth-doped sapphire crystal is in the form of a deposited film on the sapphire substrate.

2. The method for making a rare earth-doped sapphire crystal according to claim 1 wherein the sapphire substrate has an orientation of A, M, R or C-plane.

3. The method for making a rare earth-doped sapphire crystal according to claim 2 wherein the sapphire substrate has been annealed in a furnace in air to improve the surface morphology by creating atomic terraces.

4. The method for making a rare earth-doped sapphire crystal according to claim 3 wherein the rare earth element is neodymium (Nd), erbium (Er), ytterbium (Yb), thulium (Tm), holmium (Ho), or a combination thereof.

5. The method for making a rare earth-doped sapphire crystal according to claim 4 wherein the source of aluminum and the source of the rare earth element are deposited onto the sapphire substrate under an overpressure of oxygen.

6. The method for making a rare earth-doped sapphire crystal according to claim 5 wherein the source of aluminum is Al₂O₃, elemental aluminum (Al), or a combination thereof.

7. The method for making a rare earth-doped sapphire crystal according to claim 5 wherein the source of neodymium (Nd) is Nd₂O₃, elemental neodymium (Nd), or a combination thereof.

8. The method for making a rare earth-doped sapphire crystal according to claim 7 wherein the flux of neodymium (Nd) is adjusted relative to the flux of aluminum (Al) to yield a desired dopant concentration.

9. A single phase rare earth doped sapphire crystal in which the rare earth ions are on the aluminum sites and the concentration of rare earth ions exceeds 0.1 atomic percent.

10. The single phase rare earth doped sapphire crystal according to claim 9 wherein the rare earth ions include neodymium (Nd), and wherein the Nd ion concentration exceeds 0.1 atomic percent.

11. The single phase rare earth doped sapphire crystal according to claim 9 wherein the rare earth ions are neodymium (Nd), and wherein the crystal is capable of producing sharp optical emission lines at wavelengths of between 880-950 nm, or between 1070-1140 nm, or between 1380-1450 nm.

12. The single phase rare earth doped sapphire crystal according to claim 9 wherein the rare earth ions are neodymium (Nd), and wherein the crystal is capable of producing dominant optical emission lines at wavelengths of about 1096 nm, or about 910 nm, or about 1389 nm.

13. The single phase rare earth doped sapphire crystal according to claim 12 wherein the crystal is capable of producing a dominant optical emission line at a wavelength of about 1096 nm, and having a σ-τ product of about 114×10⁻²⁴ cm² for the emission line at about 1096 nm.

14. The single phase rare earth doped sapphire crystal according to claim 12 wherein the concentration of neodymium (Nd) ions is up to about 2 atomic percent relative to the aluminum (Al) concentration.

15. The single phase rare earth doped sapphire crystal according to claim 12 wherein the concentration of neodymium (Nd) ions is up to about 10 atomic percent relative to the aluminum (Al) concentration.

16. The single phase rare earth doped sapphire crystal according to claim 9 wherein the rare earth ions are neodymium (Nd), and wherein the crystal has an absorption peak at about 825 nm, or about 833 nm when excited using excitation spectroscopy.
